(19) United States
(12) Patent Application Publication
(10) Pub. No.: US 2021/0126425 A1
(43) Pub. Date: Apr. 29, 2021

(54) OPTOELECTRONIC PACKAGE AND MANUFACTURING METHOD THEREOF

(71) Applicant: Advanced Semiconductor Engineering, Inc., Kaohsiung (TW)

(72) Inventors: Chang-Yu LIN, Kaohsiung (TW); Chi-Han CHEN, Kaohsiung (TW); Pei-Jung YANG, Kaohsiung (TW)

(73) Assignee: Advanced Semiconductor Engineering, Inc., Kaohsiung (TW)

(21) Appl. No.: 16/663,091

(22) Filed: Oct. 24, 2019

(51) Int. Cl. H01S 5/022; G02B 6/12; H01S 5/028; H01S 5/024

(52) U.S. Cl. CPC H01S 5/02236; G02B 6/12004; H01S 5/02272; H01S 5/028; G02B 2006/12121; H01S 5/02288; H01S 5/02284; H01S 5/0224; H01S 5/02469

(57) ABSTRACT

An optoelectronic package includes a substrate having a first surface and a second surface opposite to the first surface, an optoelectronic device on the first surface of the substrate, and a first conductive through via connecting the first surface and the second surface of the substrate. The optoelectronic device is electrically connected to the first conductive through via. A method for manufacturing the optoelectronic package is also provided.

### BACKGROUND

### 1. Technical Field

The present disclosure relates to a photonic integrated circuit, particularly, to a photonic integrated circuit including an optoelectronic package.

### 2. Description of the Related Art

To adapt for the development of 5G and cloud computing, communication bandwidth plays an important role. Optical communication is adopted as a main direction for greater bandwidth communication since a comparative cable can no longer cater the need. Edge coupling laser is widely used as a signal source in optical communication device package. An edge coupling laser die can be integrated with an IC by a face-up fashion or a face-down fashion.

In a comparative face-down packaging fashion, an active surface of the edge coupling laser die faces and bonds to a carrier with integrated circuit to form a photonic integrated circuit (PIC). An electrode on the active surface of the edge coupling laser is bonded to the PIC carrier surface by alloying, which is difficult to perform an active alignment when bonding the laser die to the PIC carrier. In addition, conductive pattern on the PIC carrier has to be deliberately designed to wire the electrical path from the face-down electrode of the laser die to power input and not obstructing optical path. Moreover, after integration, the laser die is exposed from the PIC package, rendering the laser die fairly fragile to the environment.

### SUMMARY

In some embodiments, the present disclosure provides an optoelectronic package, including a substrate having a first surface and a second surface opposite to the first surface, an optoelectronic device on the first surface of the substrate, and a first conductive through via connecting the first surface and the second surface of the substrate. The optoelectronic device is electrically connected to the first conductive through via.

In some embodiments, the present disclosure provides a photonic integrated circuit, including a carrier having a top surface, a filled trench in the carrier and open at the top surface, a waveguide adjacent to the filled trench and proximal to the top surface, and an optoelectronic package on the top surface, having an optoelectronic device in the filled trench and aligning to the waveguide.

In some embodiments, the present disclosure provides method for manufacturing an optoelectronic package, the method includes providing a substrate having a first surface and a second surface, forming a first through via connecting the first surface and the second surface in the substrate, filling conductive materials in the first through via to form a first conductive through via, and bonding an optoelectronic device on the first surface and electrically connecting to the first conductive through via.

### BRIEF DESCRIPTION OF THE DRAWINGS

Aspects of the present disclosure are readily understood from the following detailed description when read with the accompanying figures. It should be noted that various features may not be drawn to scale. In fact, the dimensions of the various features may be arbitrarily increased or reduced for clarity of discussion.

FIG. 1A illustrates a cross-sectional view of an optoelectronic package according to some embodiments of the present disclosure.

FIG. 1B illustrates a cross-sectional view of an optoelectronic package according to some embodiments of the present disclosure.

FIG. 1C illustrates a cross-sectional view of an optoelectronic package according to some embodiments of the present disclosure.

FIG. 2 illustrates a top view of an optoelectronic package according to some embodiments of the present disclosure.

FIG. 3 illustrates a cross-sectional view of a photonic integrated circuit (PIC) according to some embodiments of the present disclosure.

FIG. 4 illustrates a cross-sectional view of a PIC according to some embodiments of the present disclosure.

FIG. 5 illustrates a top view of a PIC according to according to the PIC in FIG. 4.

FIG. 6 illustrates a cross-sectional view of a PIC according to some embodiments of the present disclosure.

FIG. 7A, FIG. 7B, FIG. 7C, FIG. 7D, FIG. 7E, and FIG. 7F illustrate cross sectional views of intermediate products during various manufacturing operations of an optoelectronic package according to some embodiments of the present disclosure.

FIG. 8A, FIG. 8B, FIG. 8C, and FIG. 8D illustrate cross sectional views of intermediate products during various manufacturing operations of a PIC according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are specified with respect to a certain component or group of components, or a certain plane of a component or group of components, for the orientation of the component(s) as shown in the associated figure. It should be understood that the spatial descriptions used herein are for purposes of illustration only, and that practical implementations of the structures described herein can be spatially arranged in any orientation or manner, provided that the merits of embodiments of this disclosure are not deviated from by such arrangement.

In some embodiments, present disclosure provides a substrate having at least a conductive trough via to be integrated with the laser die in order to form an optoelectronic package. The optoelectronic package is then integrated to a PIC carrier. The laser die is bonded to a first surface of the substrate, and electrical connection of the laser die can be accessed through a second surface opposite to the first surface of the substrate by the conductive through via. The optoelectronic package is then connected to the PIC carrier by embedding the laser die in a filled trench of the PIC carrier and forming electrical connection between the second surface of the substrate to the PIC carrier.

By having the package structure described in the present disclosure, the laser die can be integrated with a face-down fashion while performing active alignment. In addition, the electrical access to the laser die is routed to a second surface of the substrate, which is situated at an opposite side of the active surface of the laser die, reducing routing complexity. The conductive through via and electrical routing on the substrate can provide additional heat dissipation channel to the laser die. Moreover, the laser die is embedded in the filled trench of the PIC carrier. Surrounded by the curable materials in the filled trench, laser die is better protected from the environment.

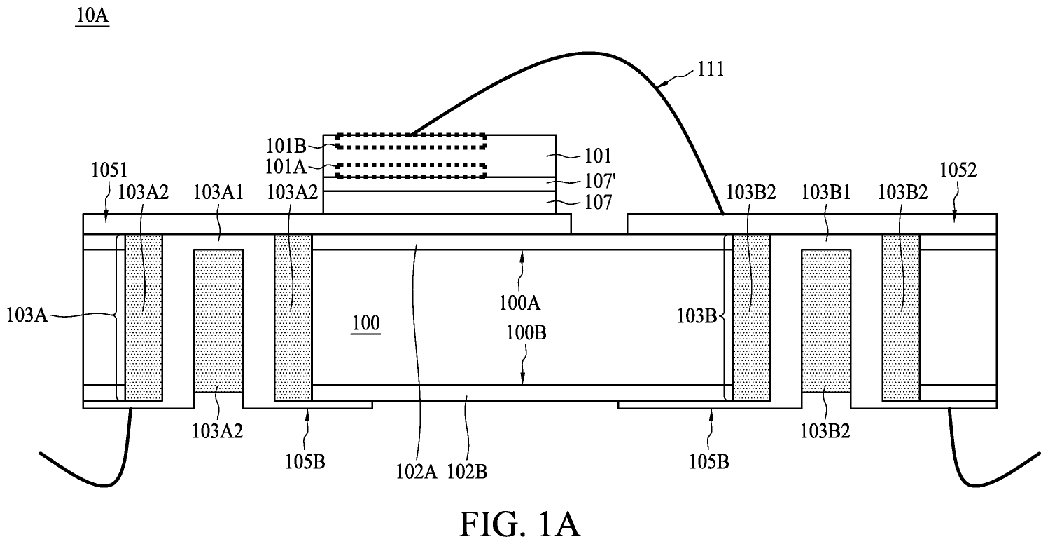

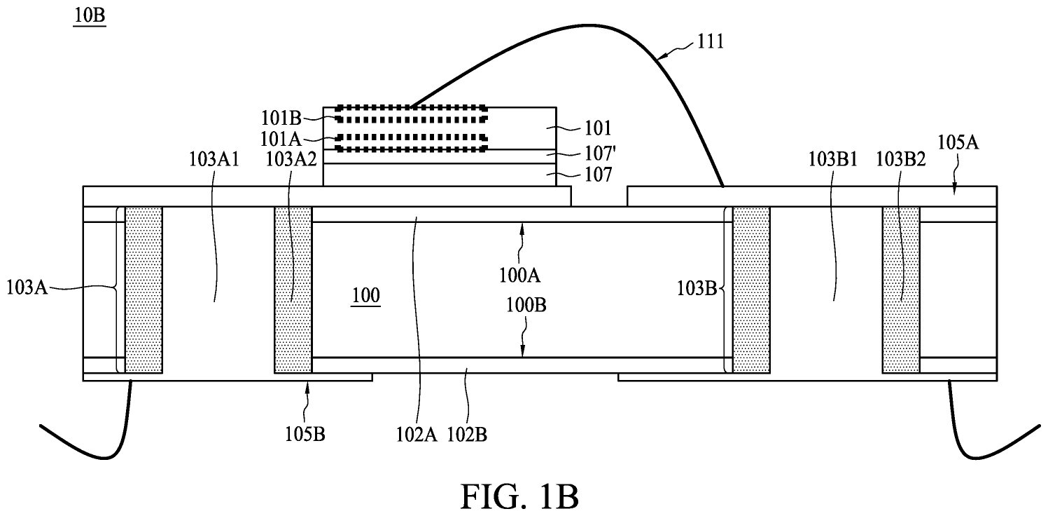

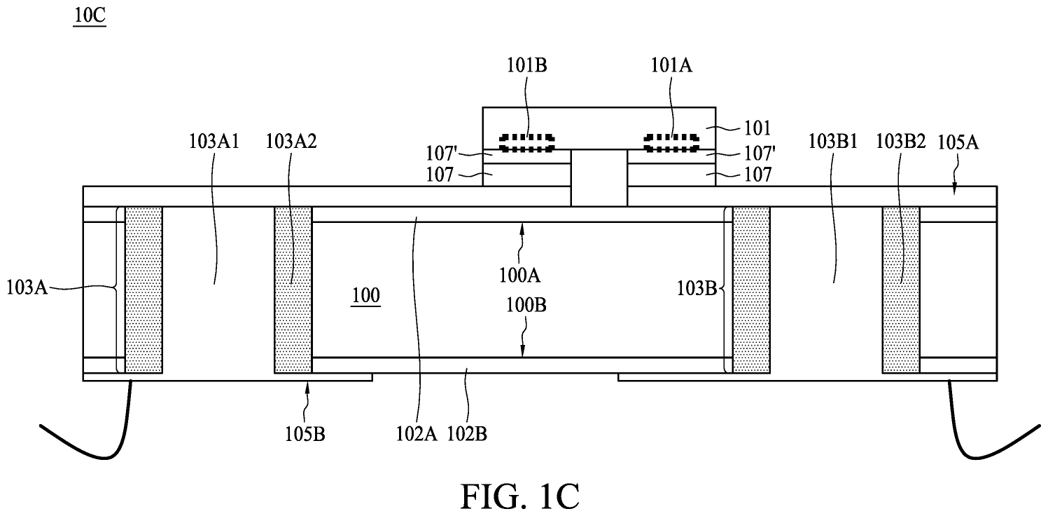

Referring to FIG. 1A, FIG. 1A illustrates a cross-sectional view of an optoelectronic package 10A according to some embodiments of the present disclosure. In FIG. 1A, the optoelectronic package 10A includes a substrate 100 and an optoelectronic device 101 stacked over the substrate 100. In some embodiments, the substrate 100 may be composed of suitable material allowing a through via formation. For example, the substrate 100 may be a silicon substrate. The substrate 100 has a first surface 100A and a second surface 100B opposite to the first surface 100A. A through via 103A connects the first surface 100A and the second surface 100B for electrical connection between components on the two surfaces. In some embodiments, more than one through via can be formed in the substrate 100 of an optoelectronic package 10A for electrical connection between components on the two surfaces.

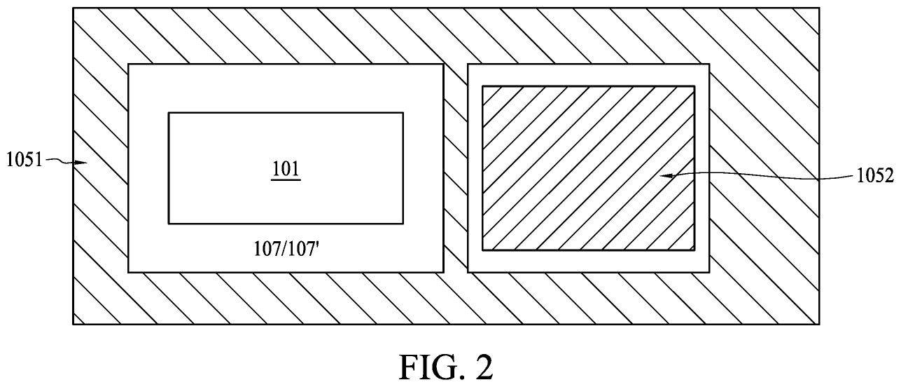

Conductive patterns 1051 and 1052 are formed over the first surface 100A of the substrate 100 to electrically couple to the electrodes of the optoelectronic device 101 to at least one of the through vias 103A and 103B. Referring to FIG. 1A and FIG. 2, the conductive patterns 1051 and 1052 can be electrically separated from a top view perspective. The conductive pattern 1051 may be in contact with a conductive bump 107 and the optoelectronic device 101, whereas the conductive pattern 1052 can be separated from the conductive bump 107 and the optoelectronic device 101. Electrical coupling between the optoelectronic device 101 and the conductive pattern 1052 can be achieved by other manner, for example, wire bonding. In some embodiments, the conductive patterns 1051 and 1052 can be an under bump metallurgy (UBM) structure including one or more conductive patterns.

In some embodiments, the through via 103A includes a conductive portion 103A1 and an insulating portion 103A2. The conductive portion 103A1 is electrically connected to the conductive pattern 1051. The insulating portion 103A2 fills the rest of the space in the open trench of the through via 103A. As shown in FIG. 1A, the conductive portion 103A1 and the insulating portion 103A2 share a coplanar surface adjacent to the first surface 100A and in contact with the conductive pattern 1051. The conductive portion 103A1 covers a side portion of the insulating portion 103A2 adjacent to the second surface 100B and form conductive pattern 105B over the second surface 100B. The conductive portion 103A1 exposes a center portion of the insulating portion 103A2 adjacent to the second surface 100B. In some embodiments, the conductive pattern 105B on the second surface 100B may include a redistribution layer (RDL).

In some embodiments, the through via 103B includes a conductive portion 103B1 and an insulating portion 103B2. The conductive portion 103B is electrically connected to the conductive pattern 1052. The insulating portion 103B2 fills the rest of the space in the open trench of the through via 103B. As shown in FIG. 1A, the conductive portion 103B1 and the insulating portion 103B2 share a coplanar surface adjacent to the first surface 100A and in contact with the conductive pattern 1052. The conductive portion 103B1 covers a side portion the insulating portion 103B2 adjacent to the second surface 100B and form conductive pattern 105B over the second surface 100B. The conductive portion 103B1 exposes a center portion of the insulating portion 103B2 adjacent to the second surface 100B. In some embodiments, the conductive pattern 105B on the second surface 100B may include a redistribution layer (RDL).

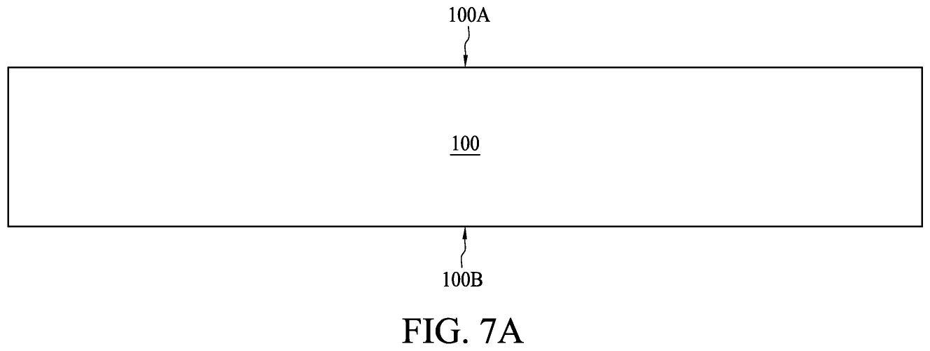

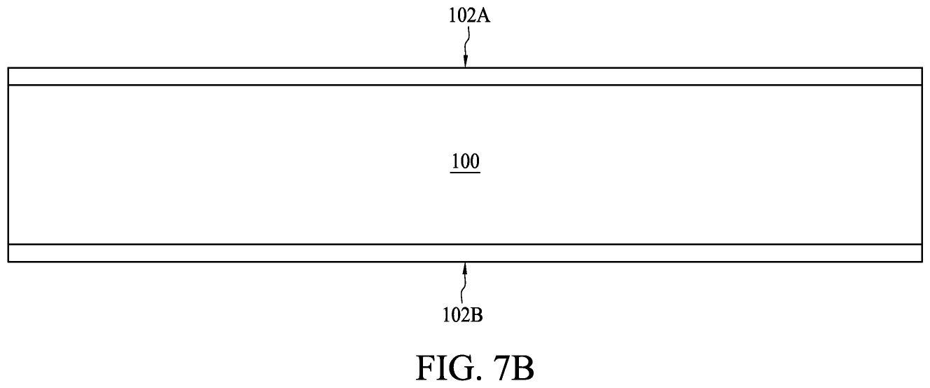

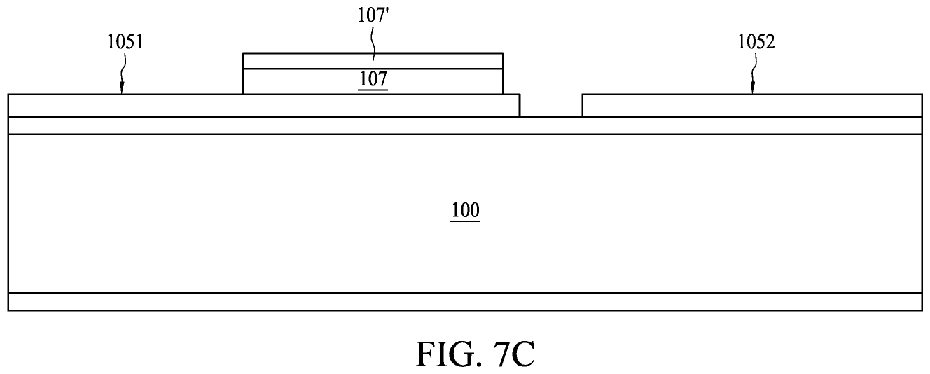

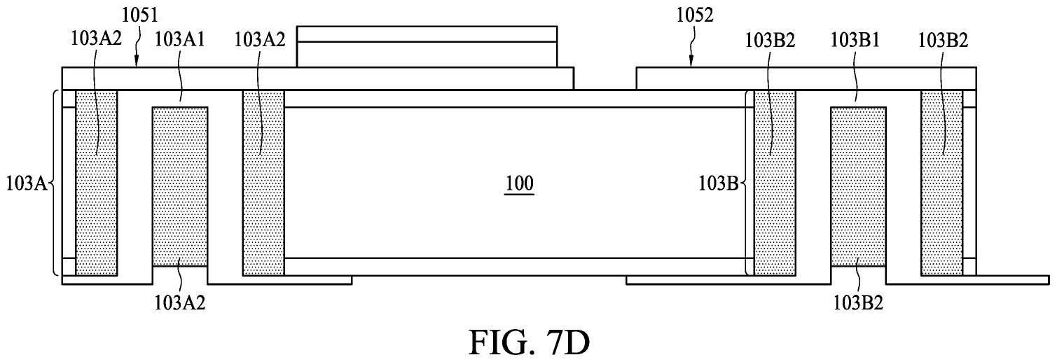

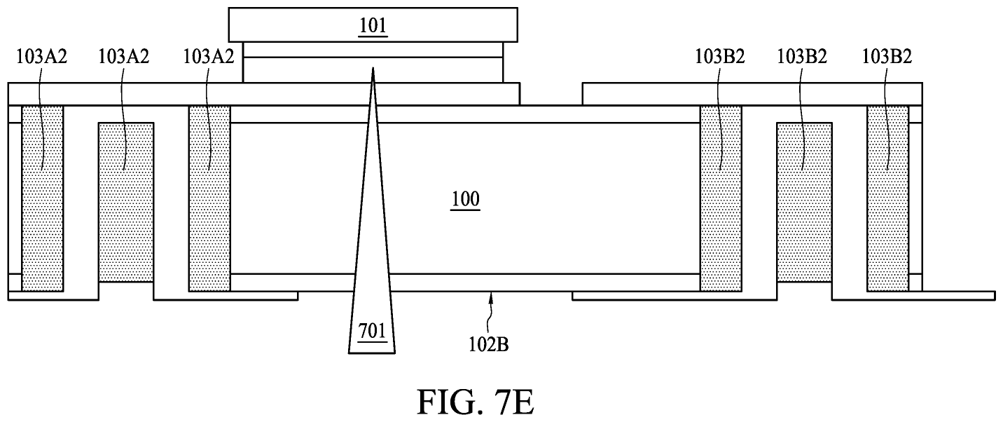

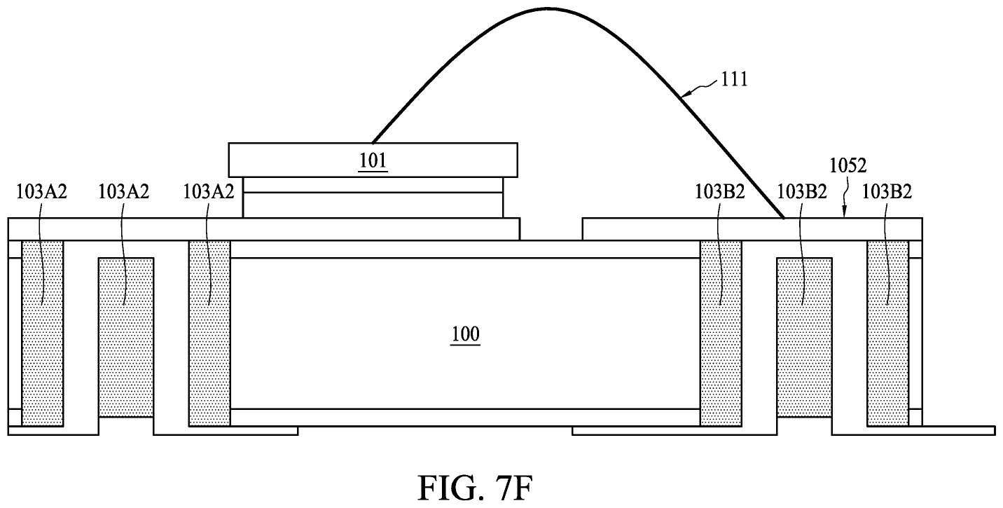

In some embodiments, the optoelectronic device 101 is stacked over the first surface 100A through a conductive bump 107/107′. In some embodiments, the conductive bump 107/107′ includes AuSn solder bump. In some embodiments, the conductive bump 107/107′ includes an AuSn solder layer 107 and a gold layer 107′. However, other suitable conductive materials can be applied in the present disclosure and serving as a conductive medium between the optoelectronic device 101 and the through via 103A. Referring to FIG. 1A and FIG. 2, an area of the conductive bump 107/107′ can be greater than an area of the optoelectronic device 101 from a top view perspective. In some embodiments, an area of the conductive bump 107/107′ can be substantially equal to an area of the optoelectronic device 101 from a top view perspective. In some embodiments, the through via 103A is free from overlapping with a projection of optoelectronic device 101, alternatively, the through via 103A is free from overlapping with a projection of the conductive bump 107/107′. During manufacturing operation as described in FIG. 7F, the conductive bump is transformed into a molten state by performing a laser heating operation irradiating from the second surface 100B of the substrate 100. The laser applied in such operation is transparent to a silicon substrate, thereby other materials which may absorb energy of the applied laser may not be disposed on the laser propagation path in the substrate 100. For the laser to enter the substrate 100 from the second surface 100B and exit the substrate from the first surface 100A, an antireflective coating 102B and 102A may be formed on the second surface 100B and the first surface 100A, respectively.

In some embodiments, the optoelectronic device 101 is an edge emitting laser. A first electrode 101A is adjacent to the bottom of the optoelectronic device 101 and is electrically coupled to the conductive pattern 1051 through the conductive bump 107′/107. A second electrode 101B is adjacent to the top of the optoelectronic device 101 and is electrically coupled to the conductive pattern 1052 through a bonding wire 111. The conductive pattern 1051 further transfer the electronic signal from the first surface 100A to the second surface 100B of the substrate 100 through the conductive portion 103A1 of the through via 103A. Similarly, the conductive pattern 1052 further transfer the electronic signal from the first surface 100A to the second surface 100B of the substrate 100 through the conductive portion 103B1 of the through via 103B.

FIG. 1B illustrates a cross-sectional view of an optoelectronic package 10B according to some embodiments of the present disclosure. The optoelectronic package 10B is similar to the optoelectronic package 10A except that the through via 103A in FIG. 1B has a different structure than the through via 103A in FIG. 1A. As illustrated in FIG. 1B, the through via 103A includes a conductive portion 103A1 and an insulating portion 103A2. The conductive portion 103A1 is electrically connected to the conductive pattern 1051. The insulating portion 103A2 fills the rest of the space in the open trench of the through via 103A. As shown in FIG. 1B, the conductive portion 103A1 and the insulating portion 103A2 share a coplanar surface adjacent to the first surface 100A and in contact with the conductive pattern 1051. The conductive portion 103A1 covers a side portion the insulating portion 103A2 adjacent to the second surface 100B and form conductive pattern 105B over the second surface 100B. A center portion of the through via 103A is filled with conductive portion 103A1. The through via 103A in FIG. 1B provides better heat dissipation channel and lower electrical resistance compared to that in FIG. 1A, therefore can be applied on an optoelectronic package specifying superior thermal dissipation and better electrical connection.

FIG. 1C illustrates a cross-sectional view of an optoelectronic package 10C according to some embodiments of the present disclosure. The optoelectronic package 10C is similar to the optoelectronic package 10B except that the optoelectronic device 101 is electrically connected to the conductive pattern 1052 through a conductive bump 107/107′ instead of a bonding wire. As illustrated in FIG. 1C, the first electrode 101A and the second electrode 101B are both reside on the bottom of the optoelectronic device 101, for example, an edge-emitting laser diode. The optoelectronic device 101 is arranged to dispose across the adjacent conductive patterns 1051 and 1052, connecting the first electrode 101A to the conducive pattern 1051 through the first conductive bump 107/107′, and connecting the electrode 101B to the conducive pattern 1052 through the second conductive bump 107/107′. Similar to previous description, the first conductive bump 107/107′ and the second conductive bump 107/107′ are free from overlapping with any of the through vias 103A and 103B.

FIG. 2 illustrates a top view of an optoelectronic package according to some embodiments of the present disclosure. Referring to FIG. 1A and FIG. 2, the optoelectronic device 101 is bonded or electrically connected to the conducive pattern 1051 over the first surface 100A of the substrate 100. The conductive pattern 1052 is separated from the conductive pattern 1051 and electrically connected to the optoelectronic device 101 through other connection means such as a bonding wire. In some embodiments as illustrated in FIG. 1C, the optoelectronic 101 crosses over the separation between the conductive pattern 1051 and conductive pattern 1052, connecting to each of the conductive patterns 1051 and 1052 through two separate conductive bumps.

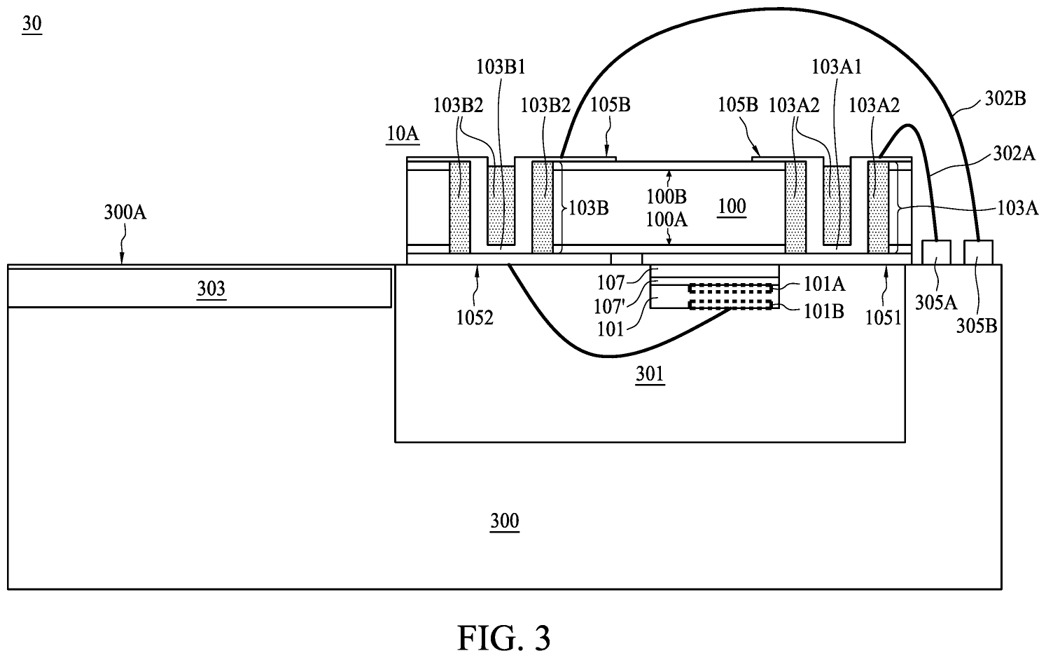

FIG. 3 illustrates a cross-sectional view of a photonic integrated circuit (PIC) 30 according to some embodiments of the present disclosure. The PIC 30 includes a carrier 30 having a top surface 300A receiving an optoelectronic package 10A. The carrier 30 has a filled trench 301 open at the top surface 300A. In some embodiments, the filled trench 301 is filled with polymeric material such as UV glue, which is transparent to the electromagnetic signal emitting from the optoelectronic device 101. The UV glue solidifies after UV treatment and provides mechanical support to the optoelectronic package 10A. The cured, polymeric materials in the filled trench 301 possess a top surface substantially coplanar with the top surface 300A of the carrier 300. The PIC 30 further includes a waveguide 303 adjacent to the filled trench 301 and adjacent to the top surface 300A. In some embodiments, the waveguide 303 is embedded or at least partially embedded in the carrier 300. The waveguide 303 is laterally aligned to the optoelectronic device 101 of the optoelectronic package 10A. Alternatively stated, when the optoelectronic device 101, for example, an edge-emitting laser diode, emits a laser beam (dotted lines) from the left edge, the laser beam subsequently enters the waveguide 303 in accordance with the lateral alignment arrangement.

Identical numeric labels in optoelectronic package 10A of FIG. 3 correspond to substantial equivalent components in that of FIG. 1A and can be referred thereto. The conductive portion 103A1 electrically connecting to the conductive pattern 1051 covers a side portion of the insulating portion 103A2 adjacent to the second surface 100B and forms conductive pattern 105B over the second surface 100B. The conductive portion 103A1 exposes a center portion of the insulating portion 103A2 adjacent to the second surface 100B. In some embodiments, the conductive pattern 105B on the second surface 100B may include a redistribution layer (RDL). The conductive pattern 105B further connect to a conductive pad 305A on the top surface 300A of the carrier 300 via a conductive channel, for example, a bonding wire 302A. Similarly, the conductive portion 103B1 electrically connecting to the conductive pattern 1052 covers a side portion of the insulating portion 103B2 adjacent to the second surface 100B and forms conductive pattern 105B over the second surface 100B. The conductive portion 103B1 exposes a center portion of the insulating portion 103B2 adjacent to the second surface 100B. In some embodiments, the conductive pattern 105B on the second surface 100B may include a redistribution layer (RDL). The conductive pattern 105B further connect to a conductive pad 305B on the top surface 300A of the carrier 300 via a conductive channel, for example, a bonding wire 302B. As illustrated in FIG. 3, the conductive pattern 1051 electrically connects to the conductive portion 103A1 of the through via 103A, and the conductive pattern 1052 electrically connects to the conductive portion 103B1 of the through via 103B.

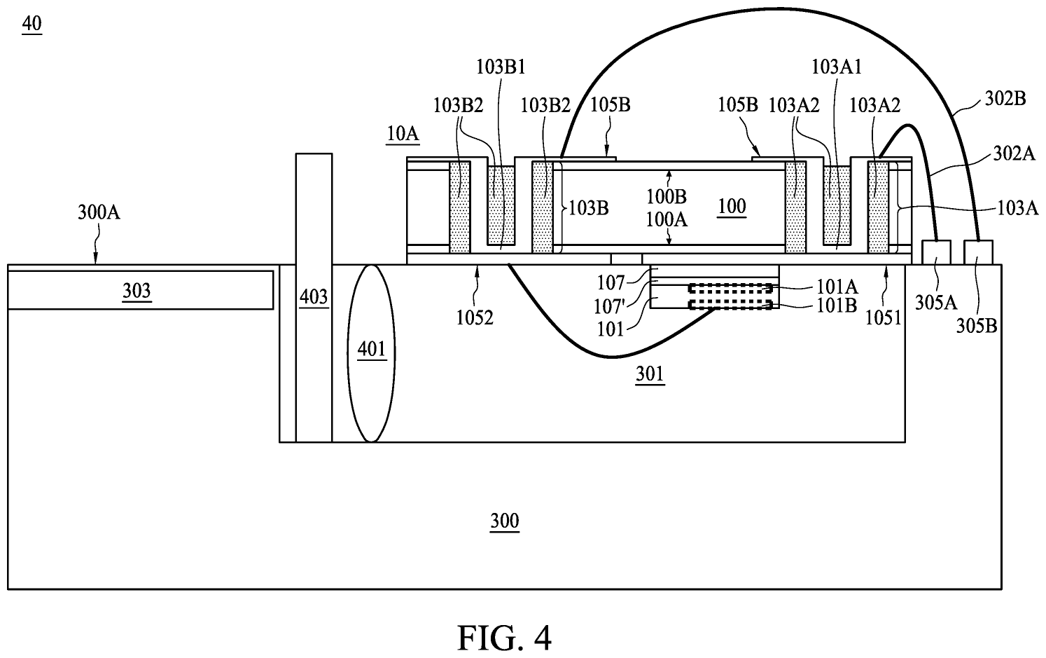

FIG. 4 illustrates a cross-sectional view of a PIC 40 according to some embodiments of the present disclosure. The PIC 40 is similar to the PIC 30 except that the optical elements can be optionally disposed in the filled trench 301 between the optoelectronic package 10A and the waveguide 303. In some embodiments, the optical elements include a lens 401 and a rotator 403. The optical elements can be fixed in the cured polymeric materials and disposed on the beam path emitting from the optoelectronic device 101. In some embodiments, a bottom of the optical component may or may not touch a bottom of the filled trench 301 since the cured polymeric material may provide mechanical support to the optical elements.

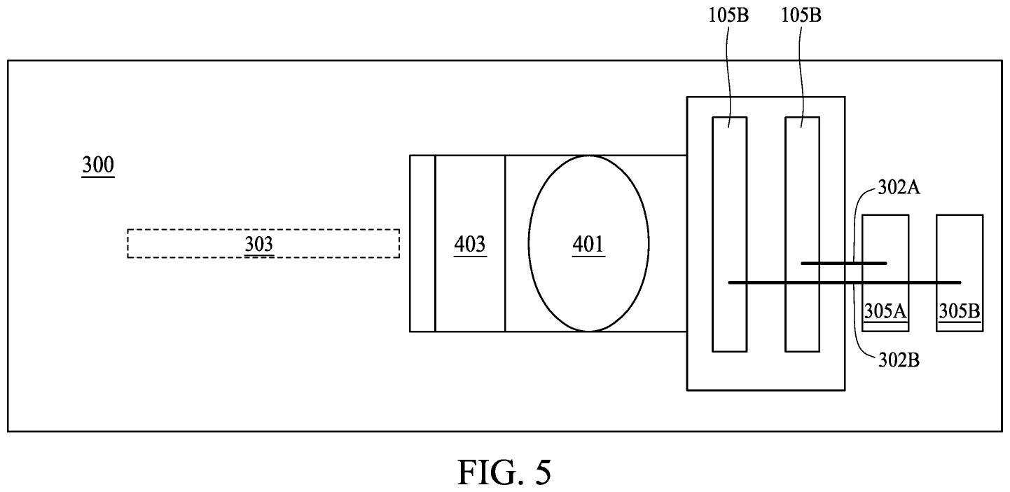

FIG. 5 illustrates a top view of a PIC according to the PIC 40 in FIG. 4. Referring to FIG. 4 and FIG. 5, the contact pad 305A on the top surface 300A of the carrier 300 can be electrically coupled to the conductive pattern 105B and conductive pattern 1051 of the optoelectronic package 10A through the bonding wire 302A. Similarly, the conductive pad 305B on the top surface 300A of the carrier 300 is electrically coupled to the conducive pattern 105B and conductive pattern 1052 of the optoelectronic package 10A through the bonding wire 302B. In some embodiments, a first portion of the optoelectronic package 10A proximal to the through via 103A is stacked on the top surface 300A of the carrier 300. A second portion of the optoelectronic package 10B proximal to the through via 103B and the optoelectronic device 101 is stacked on the top surface 300A of the filled trench 301. Optionally, the lens 401 and the rotator 403 are disposed between the waveguide 303 and the optoelectronic package 10A.

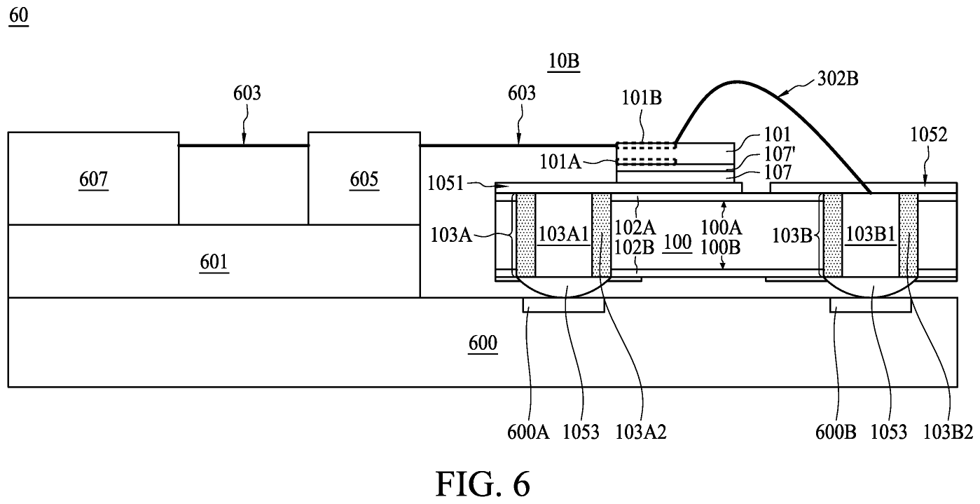

FIG. 6 illustrates a cross-sectional view of a PIC 60 according to some embodiments of the present disclosure. The optoelectronic package 10B is disposed on a printed circuit board (PCB) 600 by flip-chip bonding. The conductive portion 103A1 of the through via 103A is connected to a contact pad 600A on the PCB through a solder bump 1053 or its equivalent, and the conducive portion 103B1 of the through via 103B is connected to a contact pad 600B on the PCB through a solder bump 1053 or its equivalent. The contact pad 600A is electrically coupled to the first electrode 101A through the conductive path including the solder bump 1053, the conductive portion 1031A of the through via 103A, the conductive pattern 1051, and the conductive bump 107/107′. Similarly, the contact pad 600B is electrically coupled to the second electrode 101B through the conductive path including the solder bump 1053, the conductive portion 1031B of the through via 103B, the conductive pattern 1052, and the bonding wire 302B. The heat generated by the optoelectronic device 101 can be efficiently dissipated from the conductive portion 103A1 and 103B1 of the through via 103A, 103B, respectively.

As illustrated in FIG. 6, an optoelectronic device 101 is disposed on the first surface 100A of the substrate 100, laterally aligning to an optical element 605 with the connection of an optical fiber 603. The optical element 605 is disposed over a substrate 601 on the PCB 600 for the lateral alignment with the optoelectronic device 101. An optical switch 607 may be disposed on the substrate 601 and aligning with the optical element 605 through the connection of the optical fiber 603. In some embodiments, the thickness of the substrate is designed in consideration of the thickness of the optoelectronic package 10B.

FIG. 7A to FIG. 7F illustrate cross sectional views of an optoelectronic package during various manufacturing operations according to some embodiments of the present disclosure. In FIG. 7A, a substrate 100 is provided with a first surface 100A and a second surface 100B opposite to the first surface 100A. In FIG. 7B, antireflective coatings 102A and 102B are formed over the first surface 100A and the second surface 100B by suitable operations. In FIG. 7C, conducive patterns 1051 and 1052 are formed on the first surface 100A by blanket depositing a conductive layer, followed by a lithography operation for patterning such conductive layer. Referring back to FIG. 2, the conductive patterns 1051 and 1052 may be two discrete conductive patterns after the lithography operation. In some embodiments, the conductive patterns 1051 and 1052 are under bump metallurgy (UBM) structure. A conductive bump 107/107′ is formed on at least one of the conductive patterns 1051 and 1052. The conductive bump 107/107′ may include an AuSn solder layer 107 and a gold layer 107′. Method of forming the conductive bump 107/107′ includes electroplating or chemical plating operations.

In FIG. 7D, at least one through via is formed in the substrate 100. For example, a through via trench is formed by performing a deep reactive ion etch (DRIE) operation until the conductive pattern 1051 and/or the conductive pattern 1052 is exposed. Subsequently, a passivation material is deposited in the through via trench, lining a sidewall and a bottom of the through via trench. The passivation material at the bottom of the through via trench is then removed through a lithography operation in order to expose the conductive pattern 1051 and/or the 1052, thereby forming the insulating portion 103A2 and/or 103B2. A conductive material is then deposited in the through via trench, lining a sidewall of the insulating portion 103A2 and/or 103B2 and a bottom of the through via trench. The conductive material is in contact with the previously exposed conductive pattern 1051 and/or 1052. The conductive material extends over the second surface 100B of the substrate 100, and forming a second conductive pattern 105B or a redistribution layer (RDL). Subsequently, a passivation material is again deposited in the through via trench, filling the remaining space of the through via trench, thereby forming the insulating portion 103A2 and/or 103B2 surrounded by the conducive portion 103A1 and/or 103B1, respectively.

In FIG. 7E, an optoelectronic device 101 is bonded to the substrate 100 through the conductive bump 107/107′ on the first surface 100A of the substrate 100. A laser heating operation is performed by irradiating a laser beam 701 from the second surface 100B of the substrate 100. The laser beam enters the substrate 100 with minimum reflection due to the pre-formed antireflective layer 102B. The laser traverses the thickness direction of the substrate 100 without substantially attenuation because the material of the substrate, for example, silicon, is transparent to the laser energy. The laser then reaches the AuSn alloy layer, melting the eutectic AuSn alloy, and when the laser is turned off, the AuSn alloy solidifies and the bonding operation is completed. Since the laser beam 701 has to traverse the thickness direction of the substrate 100 and reach the AuSn alloy layer, the any of the through via 103A and 103B is free from overlapping with a projection of the AuSn alloy layer, or a portion of the conductive bump 107/107′.

In FIG. 7F, a bonding wire 111 is formed to connect a first electrode (not shown in FIG. 7F) and the conducive pattern 1052 as well as the through via 103B of the optoelectronic package.

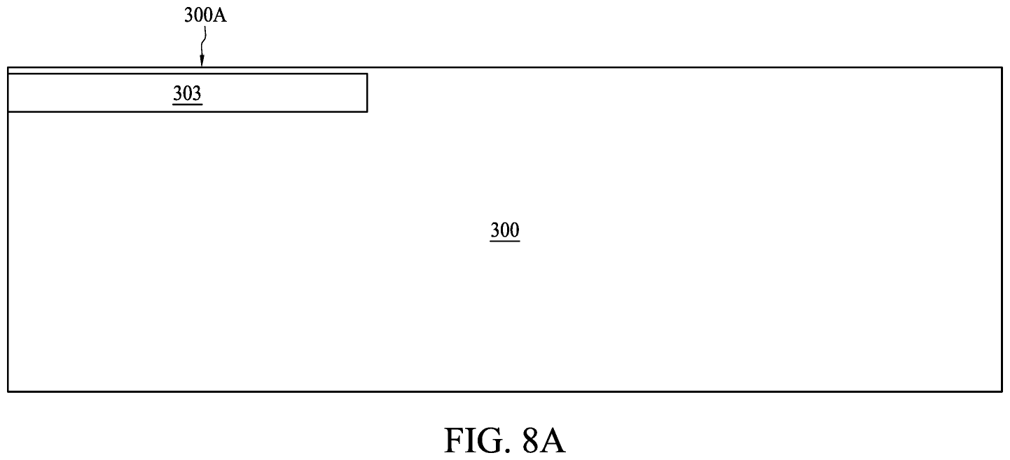

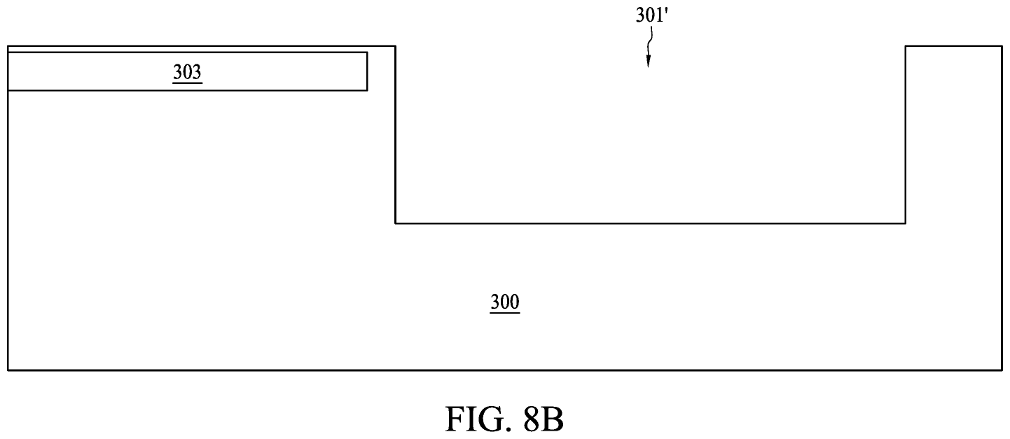

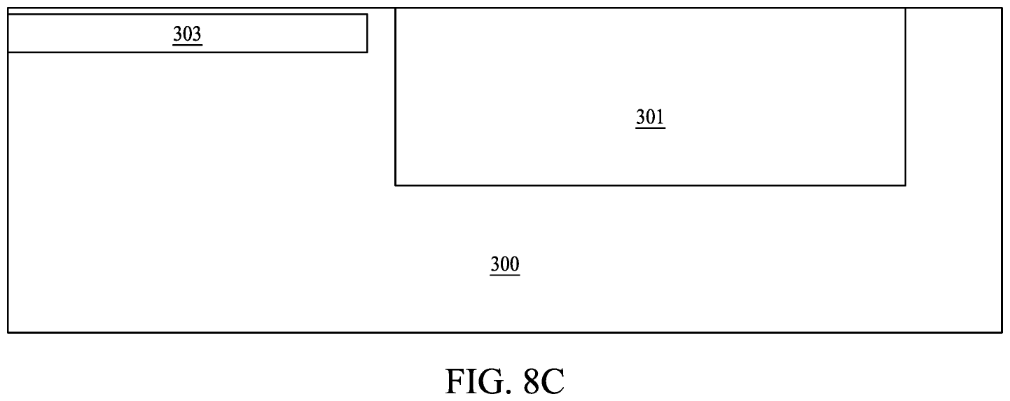

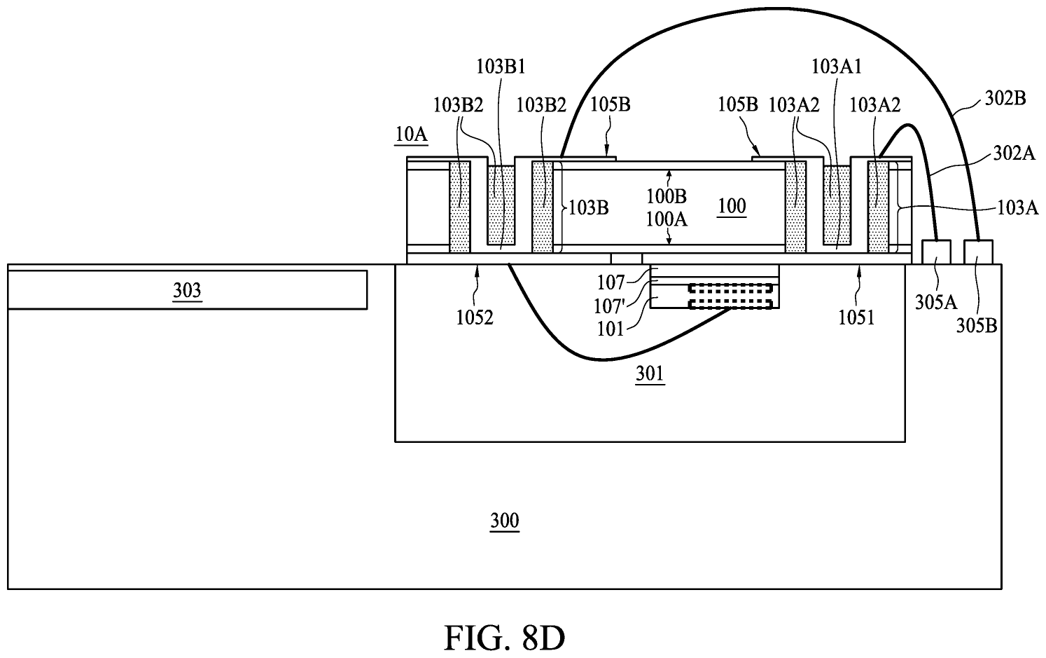

FIG. 8A to FIG. 8D illustrate cross sectional views of a PIC during various manufacturing operations according to some embodiments of the present disclosure. In FIG. 8A, a carrier 300 having a top surface 300A is provided. A waveguide 303 is embedded or partially embedded in the carrier 300 and being proximal to the top surface 300A. In FIG. 8B, a trench 301′ is formed from the top surface 300A of the carrier 300. In FIG. 8C, curable polymeric materials, for example, UV glue, is filled into the trench 301′ until a top surface of the polymeric materials is substantially coplanar with the top surface 300A of the carrier 300. In FIG. 8D, prior to curing the polymeric materials, an optoelectronic package 10A is partially disposed over the top surface 300A of the carrier 300 with the optoelectronic device 101 embedded in the polymeric materials. In some embodiments, active alignment operation is conducted to align the optoelectronic device 101 with the waveguide 303, the polymeric materials are then cured in the filled trench 301. Subsequently, connections between the through via 103A and the conductive pad 305A, as well as the through via 103B and the conductive pad 305B are subsequently formed by, for example, a wire bonding operation. In some embodiments, the bonding wire 302A is connecting the redistribution layer (RDL) on the optoelectronic package 10A to the contact pad 305A, and the bonding wire 302B is connecting the RDL on the optoelectronic package 10A to the contact pad 305B.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. The term “substantially coplanar” can refer to two surfaces within micrometers of lying along a same plane, such as within 40 within 30 within 20 within 10 or within 1 μm of lying along the same plane.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

1. An optoelectronic package, comprising:
a substrate having a first surface and a second surface opposite to the first surface;
an optoelectronic device on the first surface of the substrate; and
a first conductive through via connecting the first surface and the second surface of the substrate,
wherein the optoelectronic device is electrically connected to the first conductive through via.

2. The optoelectronic package of claim 1, further comprising a first conductive pattern on the first surface of the substrate, the first conductive pattern electrically connecting to the first conductive through via.

3. The optoelectronic package of claim 2, further comprising a conductive bump connecting a first electrode of the optoelectronic device to the first conductive pattern.

4. The optoelectronic package of claim 2, further comprising a second conductive pattern on the second surface of the substrate, the second conductive pattern electrically connected to the first conductive through via.

5. The optoelectronic package of claim 1, wherein the first conductive through via is free from overlapping with a projection of the optoelectronic device.

6. The optoelectronic package of claim 1, further comprising an anti-reflective coating over the first surface and the second surface of the substrate.

7. The optoelectronic package of claim 3, further comprising a second conductive through via connecting the first surface and the second surface of the substrate, wherein a second electrode of the optoelectronic device is electrically connected to the second conductive through via.

8. The optoelectronic package of claim 1, wherein the first conductive through via comprises an insulating portion and a conductive portion surrounding the insulating portion.

9. The optoelectronic package of claim 3, wherein the conductive bump is wider than the optoelectronic device from.

10-20. (canceled)

21. The optoelectronic package of claim 1, further comprising:
a carrier having a top surface;
a filled trench in the carrier and open at the top surface; and
a waveguide adjacent to the filled trench and proximal to the top surface;
wherein the optoelectronic package is on the top surface, and the optoelectronic device is in the filled trench and aligning to the waveguide.

22. The optoelectronic package of claim 21, wherein the filled trench is filled with a glue transparent to electromagnetic signal emitted from the optoelectronic device.

23. The optoelectronic package of claim 21, further comprising optical elements in the filled trench, disposed between the waveguide and the optoelectronic device.

24. The optoelectronic package of claim 4, further comprising a conductive channel connecting a contact pad of the carrier and the second conductive pattern on the second surface.

25. The optoelectronic package of claim 24, wherein the contact pad is on the top surface of the carrier.

26. The optoelectronic package of claim 3, further comprising a third conductive pattern on the first surface of the substrate, the third conductive pattern separated from the conductive bump.

27. The optoelectronic package of claim 26, wherein the third conductive pattern is separated from the optoelectronic device and electrically coupled to the optoelectronic device through a bonding wire.

28. The optoelectronic package of claim 3, wherein the first conductive through via is free from overlapping with a projection of the conductive bump.

29. The optoelectronic package of claim 3, wherein an area of the conductive bump is greater than an area of the optoelectronic device from a top view perspective.

30. The optoelectronic package of claim 4, wherein the second conductive pattern comprises a redistribution layer (RDL).

31. The optoelectronic package of claim 8, wherein the conductive portion and the insulating portion of the first conductive through via share a coplanar surface adjacent to the first surface of the substrate.
